(19) United States
(12) Patent Application Publication
(10) Pub. No.: US 2015/0036439 A1
(43) Pub. Date: Feb. 5, 2015

(54) SEMICONDUCTOR DEVICE

(71) Applicant: SK hynix Inc., Icheon-si (KR)

(72) Inventor: Kyong Ha LEE, Yongin-si Gyeonggi-do (KR)

(73) Assignee: SK hynix Inc., Icheon-si (KR)

(21) Appl. No.: 14/105,322

(22) Filed: Dec. 13, 2013

(30) Foreign Application Priority Data
Jul. 30, 2013 (KR) 10-2013-0089981

(51) Int. Cl. G11C 11/4093

(52) U.S. Cl. CPC G11C 11/4093
USPC 365/189.05; 365/189.011; 365/194

(57) ABSTRACT

A semiconductor device includes a command combination circuit suitable for generating a combined level signal driven in synchronization with a write command and an internal write command; and a column selection circuit suitable for generating a pulse signal which includes a pulse generated at a level transition time of the combined level signal, and a column select signal.

### CROSS-REFERENCES TO RELATED APPLICATIONS

The present application claims priority under 35 U.S.C 119(a) to Korean Patent Application No. 10-2013-0089981 filed on Jul. 30, 2013 in the Korean Intellectual Property Office, which is incorporated herein by reference in its entirety set forth in full.

### BACKGROUND

1. Technical Field

Various embodiments of the invention relate to a semiconductor device.

2. Description of Related Art

Address paths include a row address path as a path in which a word line is selected by a row address and data stored in a memory cell is amplified by a sense amplifier, a column address path as a path in which one of a plurality of output enable signals is selected by a column address, and a data path as a path in which data is transmitted to an outside through an input and output line, a sense amplifier and a data output buffer. Operations (hereinafter, referred to as ‘column operations’) regarding the column address path among the paths are controlled by a column path circuit constituted by a column decoder. The column path circuit perform operations of decoding a column address, selectively enabling one of a plurality of output enable signals and transmitting the data loaded on a bit line selected by the enabled output enable signal, to an input and output line.

In general, a semiconductor memory device such as a dynamic random-access memory (DRAM) includes a plurality of banks each of which is constituted by memory cells allocated with the same address. The semiconductor memory device configured in this way simultaneously outputs the data of the memory cells included in each bank and having the same address. To this end, the column path circuit performs column operations of decoding a column address, selectively enabling one of a plurality of output enable signals and simultaneously transmitting the data loaded on a bit line selected by the selected output enable signal in each bank, to an input and output line.

### SUMMARY

Embodiments of the invention relate to a semiconductor device capable of stably inputting and outputting data.

In an embodiment, a semiconductor device includes: a command combination circuit suitable for generating a combined level signal driven in synchronization with a write command and an internal write command; and a column selection circuit suitable for generating a pulse signal which includes a pulse generated at a level transition time of the combined level signal, and a column select signal.

In an embodiment, a semiconductor device includes: a command combination circuit suitable for generating a combined level signal driven in synchronization with a read command and an internal read command; and a column selection circuit suitable for generating a pulse signal which includes a pulse generated at a level transition time of the combined level signal, and a column select signal.

In an embodiment, a semiconductor device includes: a first command combination circuit suitable for generating a first combined level signal driven in synchronization with a write command, an internal write command, a read command and an internal read command for a first bank; and a first column selection circuit suitable for generating a first pulse signal which includes a pulse generated at a level transition time of the first combined level signal, and a first column select signal.

In an embodiment, a microprocessor comprises: a control unit suitable for receiving a signal including a command and perform an extraction or a decryption of the command or an input or output control; an operation unit suitable for performing an operation according to a decryption result of the command in the control unit; and a storage unit suitable for storing data to be operated, data corresponding to a result of the operation, and an address for the data to be operated, wherein the storage unit includes: a command combination circuit suitable for generating a combined level signal driven in synchronization with a write command and an internal write command; and a column selection circuit suitable for generating a pulse signal which includes a pulse generated at a level transition time of the combined level signal, and generate a column select signal.

Thanks to the above embodiments of the disclosure, since a level signal is generated according to a write or read command and a column select signal is generated according to the level signal, input and output of data may be stably performed.

### BRIEF DESCRIPTION OF THE DRAWINGS

The above and other aspects, features and other advantages will be more clearly understood from the following detailed description taken in conjunction with the accompanying drawings, in which:

FIG. 1 is a block diagram showing the configuration of a semiconductor device in accordance with an embodiment of the disclosure;

FIG. 2 is a circuit diagram showing an embodiment of the first level signal generation block included in the semiconductor device shown in FIG. 1;

FIG. 3 is a circuit diagram showing an embodiment of the pulse signal generation block included in the semiconductor device shown in FIG. 1;

FIG. 4 is a timing diagram explaining operations of the semiconductor device shown in FIG. 1; and

FIG. 5 is a block diagram showing the configuration of a semiconductor device in accordance with an embodiment of the disclosure.

FIG. 6 is a block diagram illustrating the semiconductor device being incorporated into a microprocessor according to an embodiment of the invention.

### DESCRIPTION OF SPECIFIC EMBODIMENTS

Hereinafter, embodiments of the invention will be described with reference to accompanying drawings. However, the embodiments are for illustrative purposes only and are not intended to limit the scope of the invention.

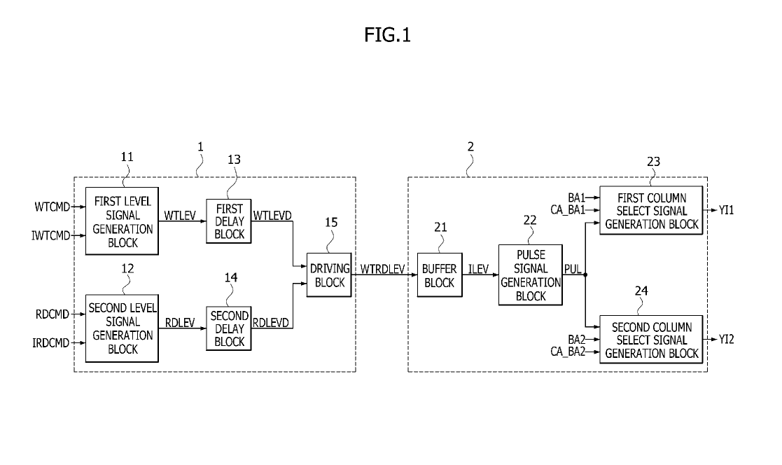

Referring to FIG. 1, a semiconductor device in accordance with an embodiment of the disclosure includes a command combination circuit 1 and a column selection circuit 2. The command combination circuit 1 includes a first level signal generation block 11, a second level signal generation block 12, a first delay block 13, a second delay block 14, and a driving block 15. The column selection circuit 2 includes a buffer block 21, a pulse signal generation block 22, a first column select signal generation block 23, and a second column select signal generation block 24. In an embodiment, the command combination circuit 1 is formed in a peripheral area, and the column selection circuit 2 is formed in a bank area. The peripheral area as an area where a control circuit for controlling operations of the semiconductor device is formed may be positioned on the edge or the center of a chip. In the bank area, cell arrays divided into banks in the semiconductor device are positioned. The cell arrays divided into banks are accessed by bank addresses.

The first level signal generation block 11 is suitable for generating a write level signal WTLEV which is driven in synchronization with a write command WTCMD and an internal write command IWTCMD. The write level signal WTLEV is driven to transition in the level thereof each time the write command WTCMD or the internal write command IWTCMD is generated. The second level signal generation block 12 is suitable for generating a read level signal RDLEV which is driven in synchronization with a read command RDCMD and an internal read command IRDCMD. The read level signal RDLEV is driven to transition in the level thereof each time the read command RDCMD or the internal read command IRDCMD is generated. The first delay block 13 is suitable for delaying the write level signal WTLEV and generating a delayed write level signal WTLEVD. The second delay block 14 is suitable for delaying the read level signal RDLEV and generating a delayed read level signal RDLEVD. The driving block 15 is suitable for driving a combined level signal WTRDLEV in response to the delayed write level signal WTLEVD generated by delaying the write level signal WTLEV and the delayed read level signal RDLEVD generated by delaying the read level signal RDLEV. The combined level signal WTRDLEV is driven in synchronization with the level of the delayed write level signal WTLEVD or the delayed read level signal RDLEVD when the write level signal WTLEV or the read level signal RDLEV is driven. The combined level signal WTRDLEV may also be driven in synchronization with the read command RDCMD and the internal read command IRDCMD. Further, the combined level signal WTRDLEV may also be driven to transition in a level thereof each time the read command RDCMD and/or the internal read command IRDCMD is generated. The internal write command IWTCMD and the internal read command IRDCMD are internal commands which are generated in a preset burst length. For instance, the internal write command IWTCMD is generated in BL8 and BL16 in a DDR2 and is generated in BL16 in a DDR3. BL8 means that a burst length is 8.

The buffer block 21 is suitable for buffering the combined level signal WTRDLEV and generating an internal level signal ILEV. The pulse signal generation block 22 is suitable for generating a pulse signal PUL in response to the internal level signal ILEV. The pulse signal generation block 22 generates the pulse signal PUL including a pulse which is generated in synchronization with the level transition time of the internal level signal ILEV which may be generated by buffering the combined level signal WTRDLEV. The first column select signal generation block 23 is suitable for generating a first column select signal YI1 from the pulse signal PUL in the case where a first column address CA_BA1 for a first bank address BA1 is inputted. The second column select signal generation block 24 is suitable for generating a second column select signal YI2 from the pulse signal PUL in the case where a second column address CA_BA2 for a second bank address BA2 is inputted. The first column select signal YI1 is a signal for controlling switches disposed between input and output lines to input and output data to and from cells which are accessed by the first column address CA_BA1 for the first bank address BA1. The second column select signal YI2 is a signal for controlling switches disposed between input and output lines to input and output data to and from cells which are accessed by the second column address CA_BA2 for the second bank address BA2.

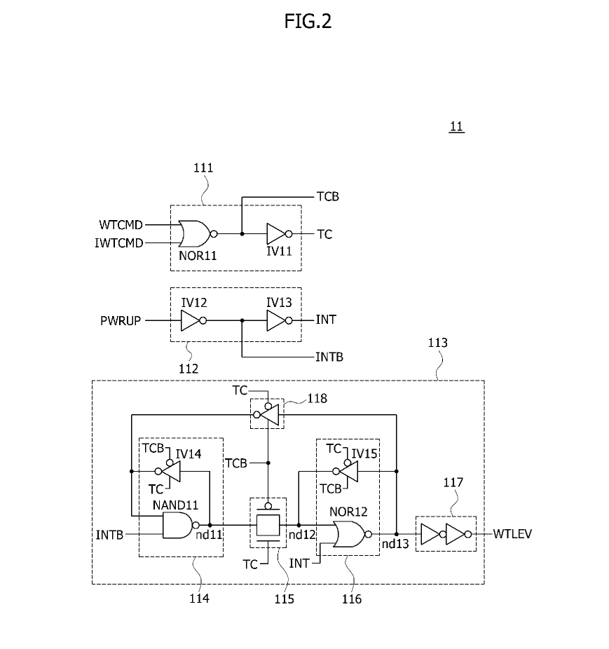

Referring to FIG. 2, the first level signal generation block 11 includes a first logic unit 111, a second logic unit 112, and a level transfer unit 113. The level transfer unit 113 includes a first latch section 114, a transfer element 115, a second latch section 116, a buffer section 117, and a feedback section 118. The first logic unit 111 includes a NOR gate NOR11 and an inverter IV11, and is suitable for generating a transmission control signal TC of a logic high level and an inverted transmission control signal TCB of a logic low level in the case where the write command WTCMD or the internal write command IWTCMD is generated to a logic high level. The second logic unit 112 includes inverters IV12 and IV13, and is suitable for buffering a power-up signal PWRUP and generate an initialization signal INT and an inverted initialization signal INTB. The power-up signal PWRUP is a signal which transitions from a logic high level to a logic low level after a power supply voltage VDD reaches a predetermined level. After the power supply voltage VDD was applied and has reached the predetermined level, the initialization signal INT may be set to a logic low level and the inverted initialization signal INTB may be set to a logic high level. While it was described in an embodiment that the levels of the initialization signal INT and the inverted initialization signal INTB are set by the power-up signal PWRUP, setting may be made such that the initialization signal INT and the inverted initialization signal INTB have predetermined levels under various conditions according to embodiments. The first latch section 114 includes a NAND gate NAND11 and an inverter IV14. The inverter IV14 inversion-buffers the signal of a node nd11 when the transmission control signal TC of the logic high level and the inverted transmission control signal TCB of the logic low level are inputted, and applies a resultant signal to the NAND gate NAND11. The transfer element 115 transfers the signal of the node nd11 when the transmission control signal TC of the logic high level and the inverted transmission control signal TCB of the logic low level are inputted. A node nd12 is also illustrated. Further, the second latch section 116 includes a NOR gate NOR12 and an inverter IV15. The inverter IV15 inversion-buffers the signal of a node nd13 when the transmission control signal TC of a logic low level and the inverted transmission control signal TCB of a logic high level are inputted, and applies a resultant signal to the NOR gate NOR12. The buffer section 117 is suitable for buffering the signal of the node nd13 and generating the write level signal WTLEV. The feedback section 118 is suitable for inversion-buffering the signal of the node nd13 when the transmission control signal TC of the logic low level and the inverted transmission control signal TCB of the logic high level are inputted, and apply a resultant signal to the NAND gate NAND11.

Operations of the first level signal generation block 11 configured as mentioned above will be described below. Before the power supply voltage VDD reaches the predetermined level, by the initialization signal INT of a logic high level and the inverted initialization signal INTB of a logic low level, the node nd11 may be initialized to a logic high level, and the node nd13 and the write level signal WTLEV may be initialized to logic low levels. After the power supply voltage VDD has reached the predetermined level, by the initialization signal INT of the logic low level and the inverted initialization signal INTB of the logic high level, the NAND gate NAND11 and the NOR gate NOR12 may operate like inverters, and inversion-buffer input signals and output resultant signals. In such a state, in the case where the write command WTCMD or the internal write command IWTCMD is generated to the logic high level, the transfer element 115 may be turned on by the transmission control signal TC of the logic high level and the inverted transmission control signal TCB of the logic low level. In the case where the write command WTCMD or the internal write command IWTCMD is generated initially, the write level signal WTLEV initialized to the logic low level may be driven to transition to a logic high level. If the write command WTCMD or the internal write command IWTCMD is generated secondly, the write level signal WTLEV of the logic high level may be driven to transition to the logic low level. The reason why the write level signal WTLEV transitions in the level thereof each time the write command WTCMD or the internal write command IWTCMD is generated resides in that, when the write command WTCMD or the internal write command IWTCMD is not generated, the signal of the node nd13 may be inversion-buffered by the feedback section 118 and may be inputted to the NAND gate NAND11 to transition the level of the node nd11.

As can be readily seen from the above descriptions, the first level signal generation block 11 generates the write level signal WTLEV which is driven to transition in the level thereof each time the write command WTCMD or the internal write command IWTCMD is generated. Since the second level signal generation block 12 may be easily realized through the configuration of the first level signal generation block 11 shown in FIG. 2 by a person skilled in the art, detailed descriptions for the configuration and operations thereof will be omitted herein.

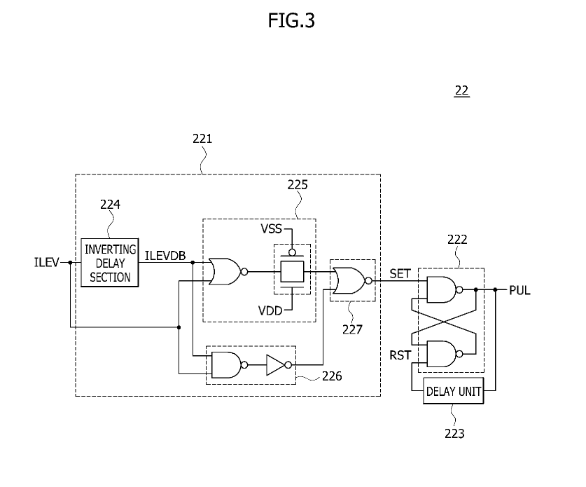

Referring to FIG. 3, the pulse signal generation block 22 includes a set signal generation unit 221, a pulse output unit 222, and a delay unit 223. The set signal generation unit 221 includes an inverting delay section 224, a first level sensing section 225, a second level sensing section 226, and a sense output section 227. The set signal generation unit 221 may be suitable for generating a set signal SET which is enabled each time a level of the internal level signal ILEV transitions. The inverting delay section 224 is suitable for inverting and delaying the internal level signal ILEV and generating a delayed and inverted internal level signal ILEVDB. The first level sensing section 225 includes a transfer gate which operates by the power supply voltage VDD and a ground voltage VSS; and the first level sensing section 225 is suitable for sensing when both the internal level signal ILEV and the delayed and inverted internal level signal ILEVDB are logic low levels and output a logic high level. The second level sensing section 226 is suitable for sensing when both the internal level signal ILEV and the delayed and inverted internal level signal ILEVDB are logic high levels and output a logic high level. The sense output section 227 is suitable for outputting a set signal SET which is enabled to a logic low level when the first level sensing section 225 or the second level sensing section 226 outputs the logic high level. The pulse output unit 222 is suitable for outputting the pulse signal PUL which may be enabled to a logic high level when the set signal SET is enabled to the logic low level and may be disabled to a logic low level when a reset signal RST is enabled to a logic low level. The pulse output unit 222 may be suitable for generating the pulse signal PUL in synchronization with the set signal SET and the reset signal RST. Since the reset signal RST is generated as the pulse signal PUL is delayed through the delay unit 223, the pulse width of the pulse included in the pulse signal PUL is set by the delay period of the delay unit 223. The pulse signal generation block 22 generates the pulse signal PUL which includes the pulse with the pulse width corresponding to the delay period of the delay unit 223, at the time the level of the internal level signal ILEV transitions.

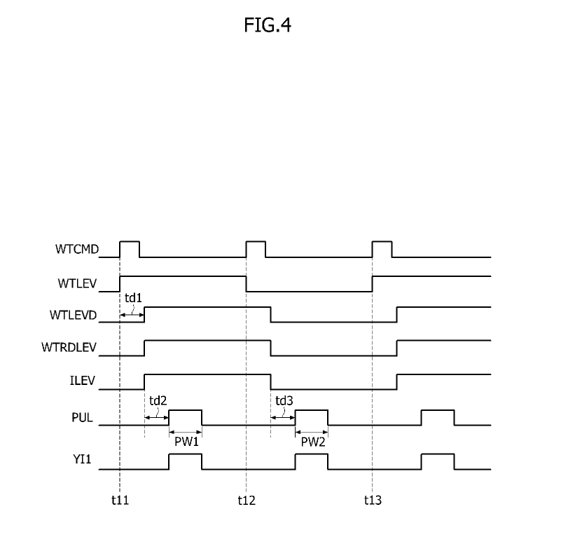

Operations of the semiconductor device in accordance with an embodiment, configured as mentioned above with reference to FIGS. 1 to 3, will be described below with reference to FIG. 4, on the assumption that the write command WTCMD is consecutively inputted 3 times.

First, at the time of t11, when the write command WTCMD is inputted firstly, the write level signal WTLEV initialized to the logic low level may be driven to transition in the level thereof to the logic high level. The combined level signal WTRDLEV is driven to a logic high level by the delayed write level signal WTLEVD which is generated through delaying the write level signal WTLEV by a first delay period td1. The combined level signal WTRDLEV is generated in the peripheral area and is transferred to the bank area. Since the combined level signal WTRDLEV is a level signal, it is stably transferred in comparison with a pulse signal even though the peripheral area and the bank area are formed to be distant from each other. The column selection circuit 2 may be applied with the combined level signal WTRDLEV and generate the internal level signal ILEV, and generate the pulse signal PUL which includes a pulse with a first pulse width PW1, when a second delay period td2 has passed from a time the internal level signal ILEV transitions from the logic low level to the logic high level. The first column select signal YI1 is generated from the pulse signal PUL in the case where the first column address CA_BA1 for the first bank address BA1 is inputted.

Next, at the time of t12, when the write command WTCMD is inputted secondly, the write level signal WTLEV of the logic high level may be driven to transition in the level thereof to the logic low level. The combined level signal WTRDLEV is driven to a logic low level by the delayed write level signal WTLEVD which is generated through delaying the write level signal WTLEV by the first delay period td1. The column selection circuit 2 is applied with the combined level signal WTRDLEV and generates the internal level signal ILEV; and the column selection circuit 2 may generate the pulse signal PUL which includes a pulse with a second pulse width PW2, when a third delay period td3 has passed from a time the internal level signal ILEV transitions from the logic high level to the logic low level. The first column select signal YI1 is generated from the pulse signal PUL in the case where the first column address CA_BA1 for the first bank address BA1 is inputted. The second delay period td2 and the third delay period td3 may be set to be the same with or different from each other according to an embodiment. The first pulse width PW1 and the second pulse width PW2 may be set to be the same with or different from each other according to an embodiment.

Finally, at the time of t13, when the write command WTCMD is inputted thirdly, the write level signal WTLEV of the logic low level may be driven to transition in the level thereof to the logic high level. Similarly to the time of t11, the combined level signal WTRDLEV is transmitted through being driven by the delayed write level signal WTLEVD. The first column select signal YI1 is generated from the pulse signal PUL in the case where the first column address CA_BA1 for the first bank address BA1 is inputted.

The above-described operations of the semiconductor device may be applied in the same manner even in the case where the internal write command IWTCMD is inputted instead of the write command WTCMD.

As is apparent from the above descriptions, the semiconductor device in accordance with an embodiment generates the combined level signal WTRDLEV which is driven to a predetermined level when one command of the write command WTCMD, the internal write command IWTCMD, the read command RDCMD and the internal read command IRDCMD is inputted. The combined level signal WTRDLEV is transmitted from the peripheral area to the bank area for the generation of a column select signal. Since the combined level signal WTRDLEV is a level signal, it may be stably transmitted in comparison with a pulse signal. Accordingly, because the column select signal may be stably generated from the combined level signal WTRDLEV, it is possible to prevent a mis-operation which is otherwise likely to occur in data input and output operations.

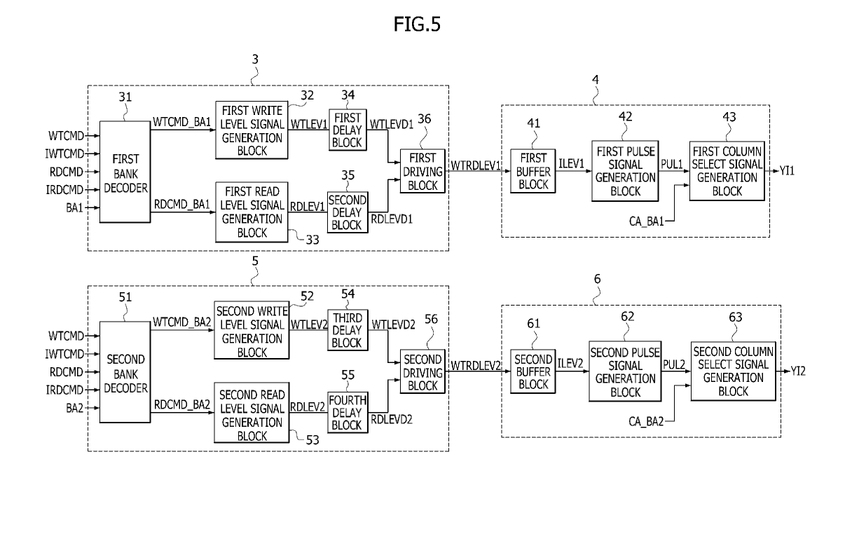

Referring to FIG. 5, a semiconductor device in accordance with an embodiment of the disclosure includes a first command combination circuit 3, a first column selection circuit 4, a second command combination circuit 5, and a second column selection circuit 6. The first command combination circuit 3 includes a first bank decoder 31, a first write level signal generation block 32, a first read level signal generation block 33, a first delay block 34, a second delay block 35, and a first driving block 36. The first column selection circuit 4 includes a first buffer block 41, a first pulse signal generation block 42, and a first column select signal generation block 43. The second command combination circuit 5 includes a second bank decoder 51, a second write level signal generation block 52, a second read level signal generation block 53, a third delay block 54, a fourth delay block 55, and a second driving block 56. The second column selection circuit 6 includes a second buffer block 61, a second pulse signal generation block 62, and a second column select signal generation block 63.

The first bank decoder 31 is suitable for generating a first bank write command WTCMD_BA1 in the case where a write command WTCMD and an internal write command IWTCMD are generated in the state in which a first bank address BA1 for accessing a first bank (not shown) is inputted. The first bank decoder 31 is suitable for generating a first bank read command RDCMD_BA1 in the case where a read command RDCMD and an internal read command IRDCMD are generated in the state in which the first bank address BA1 is inputted. The first write level signal generation block 32 is suitable for driving a first write level signal WTLEV1 to transition in the level thereof each time the first bank write command WTCMD_BA1 is generated. The first read level signal generation block 33 is suitable for driving a first read level signal RDLEV1 to transition in the level thereof each time the first bank read command RDCMD_BA1 is generated. The first delay block 34 is suitable for delaying the first write level signal WTLEV1 and generate a first delayed write level signal WTLEVD1. The second delay block 35 is suitable for delaying the first read level signal RDLEV1 and generate a first delayed read level signal RDLEVD1. The first driving block 36 is suitable for driving a first combined level signal WTRDLEV1 in response to the first delayed write level signal WTLEVD1 which may be generated by delaying the first write level signal WTLEV1 and the first delayed read level signal RDLEVD1 that may be generated by delaying the first read level signal RDLEV1. The first combined level signal WTRDLEV1 is driven in synchronization with the levels of the first delayed write level signal WTLEVD1 and the first delayed read level signal RDLEVD1 when the first write level signal WTLEV1 or the first read level signal RDLEV1 is driven. The first command combination circuit 3 may be suitable for generating the first combined level signal WTRDLEV1 which may be driven in synchronization with a write command WTCMD, an internal write command IWTCMD, a read command RDCMD, and an internal read command IRDCMD for a first bank.

The first buffer block 41 is suitable for buffering the first combined level signal WTRDLEV1 and generating a first internal level signal ILEV1. The first pulse signal generation block 42 is suitable for generating a first pulse signal PUL1 in response to the first internal level signal ILEV1 which may be generated by buffering the first combined level signal WTRDLEV1. The first pulse signal generation block 42 generates the first pulse signal PUL1 which includes the pulse generated in synchronization with the level transition time of the first internal level signal ILEV1 and may also be in synchronization with the level transition time of the first combined level signal WTRDLEV1. The first column select signal generation block 43 is suitable for generating a first column select signal YI1 from the first pulse signal PUL1 in the case where a first column address CA_BA1 and the first bank address BA1 is inputted.

The second bank decoder 51 is suitable for generating a second bank write command WTCMD_BA2 in the case where the write command WTCMD and the internal write command IWTCMD are generated in the state in which a second bank address BA2 for accessing a second bank (not shown) is inputted. The second bank decoder 51 is suitable for generating a second bank read command RDCMD_BA2 in the case where the read command RDCMD and the internal read command IRDCMD are generated in the state in which the second bank address BA2 is inputted. The second write level signal generation block 52 is suitable for driving a second write level signal WTLEV2 to transition in the level thereof each time the second bank write command WTCMD_BA2 is generated. The second read level signal generation block 53 is suitable for driving a second read level signal RDLEV2 to transition in the level thereof each time the second bank read command RDCMD_BA2 is generated. The third delay block 54 is suitable for delaying the second write level signal WTLEV2 and generate a second delayed write level signal WTLEVD2. The fourth delay block 55 is suitable for delaying the second read level signal RDLEV2 and generate a second delayed read level signal RDLEVD2. The second driving block 56 is suitable for driving a second combined level signal WTRDLEV2 in response to the second delayed write level signal WTLEVD2 and the second delayed read level signal RDLEVD2. The second combined level signal WTRDLEV2 may be driven in synchronization with the levels of the second delayed write level signal WTLEVD2 and the second delayed read level signal RDLEVD2 when the second write level signal WTLEV2 or the second read level signal RDLEV2 is driven. Accordingly, the second command combination circuit 5 may be suitable for generating the second combined level signal WTRDLEV2 driven in synchronization with the write command WTCMD, the internal write command IWTCMD, the read command RDCMD, the internal read command IRDCMD for a second bank.

The second buffer block 61 is suitable for buffering the second combined level signal WTRDLEV2 and generating a second internal level signal ILEV2. The second pulse signal generation block 62 is suitable for generating a second pulse signal PUL2 in response to the second internal level signal ILEV2. The second pulse signal generation block 62 generates the second pulse signal PUL2 which includes the pulse generated in synchronization with the level transition time of the second internal level signal ILEV2. The second pulse signal PUL2 may also have the pulse generated at the level transition time of the second combined level signal WTRDLEV2. The second column select signal generation block 63 is suitable for generating a second column select signal YI2 from the second pulse signal PUL2 in the case where a second column address CA_BA2 and the second bank address BA2 is inputted.

As is apparent from the above descriptions, the semiconductor device in accordance with an embodiment generates a combined level signal WTRDLEV for each bank which is driven to a predetermined level when one command of the write command WTCMD, the internal write command IWTCMD, the read command RDCMD and the internal read command IRDCMD is inputted. That is to say, the first combined level signal WTRDLEV1 is generated to generate the first column select signal YI1 for the first column address of the first bank, and the second combined level signal WTRDLEV2 is generated to generate the second column select signal YI2 for the second column address of the second bank. The first combined level signal WTRDLEV1 and the second combined level signal WTRDLEV2 are transmitted from a peripheral area to a bank area for the generation of the first column select signal YI1 and the second column select signal YI2. Since each of the first combined level signal WTRDLEV1 and the second combined level signal WTRDLEV2 is a level signal, it may be stably transmitted in comparison with a pulse signal. Accordingly, because the first column select signal YI1 and the second column select signal YI2 may be generated from the first combined level signal WTRDLEV1 and the second combined level signal WTRDLEV2, it is possible to prevent a mis-operation which is otherwise likely to occur in data input and output operations.

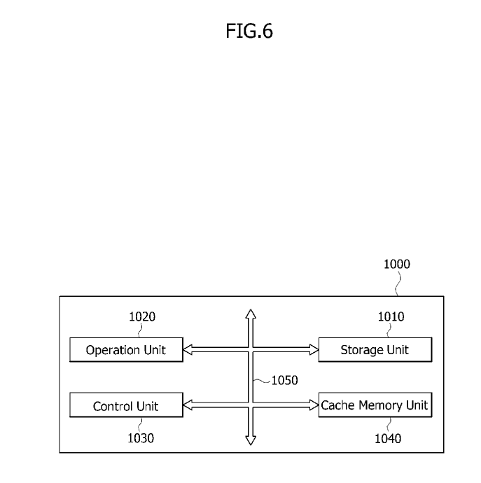

Referring to FIG. 6, a microprocessor 1000 may receive data from various external apparatuses, process the data and transmit processing results to external apparatuses. The microprocessor 1000 may include a storage unit 1010, an operation unit 1020, and a control unit 1030. The microprocessor 1000 may be a variety of processing apparatuses, such as a central processing unit (CPU), a graphic processing unit (GPU), a digital signal processor (DSP), or an application processor (AP).

The storage unit 1010 may be a unit that may store data in the microprocessor 1000 and may include various registers. The storage unit 1010 may temporarily store data to be operated in the operation unit 1020, resulting data performed in the operation unit 1020, and an address in which data to be operated is stored. The storage unit 1010 may include the semiconductor device according to the embodiments described above.

The operation unit 1020 may perform an operation in the microprocessor 1000, and perform a variety of four fundamental rules of an arithmetic operation or a logic operation depending on a decryption result of a command in the control unit 1030. The operation unit 1020 may include one or more arithmetic and logic units (ALU).

The control unit 1030 may receive a signal from the storage unit 1010, the operation unit 1020, or an external apparatus of the microprocessor 100, and may perform an extraction or decryption of a command, or input or output control, and execute a process in a program form.

The microprocessor 1000 according to the embodiment may further include a cache memory unit 1040 suitable for temporarily storing data input from an external apparatus other than the storage unit 1010 or data to be output to an external apparatus. The cache memory unit 1040 may exchange data from the storage unit 1010, the operation unit 1020, and the control unit 1030 through a bus interface 1050.

The embodiments of the invention have been disclosed above for illustrative purposes. Those skilled in the art will appreciate that various modifications, additions and substitutions are possible, without departing from the scope and spirit of the invention as disclosed in the accompanying claims.

What is claimed is:

1. A semiconductor device comprising:
a command combination circuit suitable for generating a combined level signal driven in synchronization with a write command and an internal write command; and
a column selection circuit suitable for generating a pulse signal which includes a pulse generated at a level transition time of the combined level signal, and a column select signal.

2. The semiconductor device according to claim 1, wherein the internal write command is generated in a preset burst length.

3. The semiconductor device according to claim 1, wherein the combined level signal is driven in synchronization with a read command and an internal read command.

4. The semiconductor device according to claim 3, wherein the internal read command is generated in a preset burst length.

5. The semiconductor device according to claim 4, wherein the command combination circuit comprises:
a first level signal generation block suitable for generating a write level signal driven when the write command or the internal write command is generated;
a second level signal generation block suitable for generating a read level signal driven when the read command or the internal read command is generated; and
a driving block suitable for driving the combined level signal in response to a delayed write level signal and a delayed read level signal.

6. The semiconductor device according to claim 5, wherein the write level signal is driven to transition in a level thereof each time the write command or the internal write command is generated.

7. The semiconductor device according to claim 6, wherein the read level signal is driven to transition in a level thereof each time the read command or the internal read command is generated.

8. The semiconductor device according to claim 1, wherein the column selection circuit generates a first column select signal from the pulse signal when a first column address of a first bank is inputted, and generates a second column select signal from the pulse signal when a second column address of a second bank is inputted.

9. The semiconductor device according to claim 8, wherein the column selection circuit comprises:
a pulse signal generation block suitable for generating the pulse signal in synchronization with an internal level signal generated by buffering the combined level signal;
a first column select signal generation block suitable for generating the first column select signal from the pulse signal where the first column address of the first bank is inputted; and
a second column select signal generation block suitable for generating the second column select signal from the pulse signal where the second column address of the second bank is inputted.

10. The semiconductor device according to claim 8, wherein the pulse signal generation block comprises:
a set signal generation unit suitable for generating a set signal which is enabled each time a level of the internal level signal transitions;
a pulse output unit suitable for generating the pulse signal in synchronization with the set signal and a reset signal; and
a delay unit suitable for delaying the pulse signal and generate the reset signal.

11. A semiconductor device comprising:
a command combination circuit suitable for generating a combined level signal driven in synchronization with a read command and an internal read command; and
a column selection circuit suitable for generating a pulse signal which includes a pulse generated at a level transition time of the combined level signal, and a column select signal.

12. The semiconductor device according to claim 11, wherein the internal read command is generated in a preset burst length.

13. The semiconductor device according to claim 11, wherein the combined level signal is driven to transition in a level thereof each time the read command or the internal read command is generated.

14. The semiconductor device according to claim 11, wherein the column selection circuit generates a first column select signal from the pulse signal where a first column address of a first bank is inputted, and generates a second column select signal from the pulse signal where a second column address of a second bank is inputted.

15. The semiconductor device according to claim 14, wherein the column selection circuit comprises:
a pulse signal generation block suitable for generating the pulse signal in synchronization with an internal level signal which is generated by buffering the combined level signal;
a first column select signal generation block suitable for generating the first column select signal from the pulse signal in the case where the first column address of the first bank is inputted; and
a second column select signal generation block suitable for generating the second column select signal from the pulse signal in the case where the second column address of the second bank is inputted.

16. A semiconductor device comprising:
a first command combination circuit suitable for generating a first combined level signal driven in synchronization with a write command, an internal write command, a read command and an internal read command for a first bank; and
a first column selection circuit suitable for generating a first pulse signal which includes a pulse generated at a level transition time of the first combined level signal, and a first column select signal.

17. The semiconductor device according to claim 16, wherein the internal write command and the internal read command are generated in a preset burst length.

18. The semiconductor device according to claim 16, wherein the first command combination circuit comprises:
a first bank decoder suitable for generating a first bank write command where the write command or the internal write command for the first bank is generated, and generate a first bank read command where the read command or the internal read command for the first bank is generated;
a first level signal generation block suitable for generating a first level signal which is driven in response to the first bank write command;
a second level signal generation block suitable for generating a second level signal which is driven in response to the first bank read command; and
a driving block suitable for driving the first combined level signal in response to a first delayed level signal which is generated by delaying the first level signal and a second delayed level signal which is generated by delaying the second level signal.

19. The semiconductor device according to claim 18, wherein the first column selection circuit comprises:
a pulse signal generation block suitable for generating the first pulse signal in synchronization with a first internal level signal which is generated by buffering the first combined level signal; and
a first column select signal generation block suitable for generating the first column select signal from the first pulse signal in the case where a first column address is inputted.

20. The semiconductor device according to claim 16, further comprising:
a second command combination circuit suitable for generating a second combined level signal which is driven in synchronization with the write command, the internal write command, the read command and the internal read command for a second bank; and
a second column selection circuit suitable for generating a second pulse signal which includes a pulse generated at a level transition time of the second combined level signal, and generate a second column select signal from the second pulse signal in response to a second column address.
